(19) United States
(12) Patent Application Publication
(10) Pub. No.: US 2012/0199929 A1
(43) Pub. Date: Aug. 9, 2012

(54) NEAR INFRARED CUTOFF FILTER

(75) Inventors: Katsushi KAMIJYO, Haibara-gun (JP); Hajime Hoshino, Tokyo (JP)

(73) Assignee: Asahi Glass Company, Limited, Tokyo (JP)

(21) Appl. No.: 13/450,517

(22) Filed: Apr. 19, 2012

Related U.S. Application Data
(63) Continuation of application No. PCT/JP10/69523, filed on Nov. 2, 2010.

(30) Foreign Application Priority Data
Nov. 4, 2009 (JP) 2009-253255

(51) Int. Cl. H01L 31/0232; F21V 9/04

(52) U.S. Cl. 257/432; 359/359; 257/E31.127

(57) ABSTRACT

To provide a near infrared cutoff filter at low costs, which is useful as cover glass for a solid state imaging sensor package, by providing a thin film attenuation layer for effectively shielding α rays emitted from substrate glass in a form not to influence the optical characteristics. A near infrared cutoff filter comprising substrate glass made of fluorophosphate glass containing CuO or phosphate glass containing CuO, and a thin film attenuation layer formed on at least one light-permeable surface of the substrate glass to attenuate α rays emitted from the substrate glass.

### TECHNICAL FIELD

The present invention relates to a near infrared cutoff filter useful for a cover glass for a solid state imaging sensor package, which is attached to a front opening of a package accommodating a solid state imaging sensor thereby to protect the solid state imaging sensor and to be used as a light permeable window.

### BACKGROUND ART

In recent years, downsizing, thinning and price reduction of a camera containing an optically functional component having a solid state imaging sensor such as CCD or CMOS mounted, have been rapidly in progress, and accordingly, downsizing, thinning or reduction of parts have been in progress also with respect to an optically functional component such as a camera module to be mounted.

Such an optically functional component is constituted mainly by a lens made of a glass material or plastic material to focus and lead an image to a solid state imaging sensor, a near infrared cutoff filter containing a metal complex to correct a reddish color, a low-pass filter to reduce moire or false color, a cover glass air-tightly sealed on a solid state imaging sensor package, etc.

If the cover glass used here contains α ray emitting elements (radioisotopes) in glass, it induces a transient malfunction (soft error) to the solid state imaging sensor by emitting α rays. Therefore, it is necessary to use highly purified glass raw materials wherein α ray emitting elements contained as impurities in glass are as little as possible and to produce glass by preventing inclusion of such elements also in the melting step.

The above-mentioned construction of the optically functional component has had a problem that it is difficult to make such a component to be thin due to restrictions with respect to parts to obtain the respective properties, and consequently, there is a limitation in downsizing of the camera itself.

Therefore, it has been proposed to use a near infrared cutoff filter as a cover glass in JP-A-7-281021 (Patent Document 1). According to this proposal, it is possible to prevent a soft error of a solid state imaging sensor by adjusting the contents of U and Th in the near infrared-absorbing glass to be at most certain levels. As disclosed, it is thereby possible to provide a protective filter for a solid state imaging sensor wherein the functions of cover glass and a near infrared cutoff filter are complexed, whereby soft errors can be minimized, size and weight reduction becomes possible, and cost reduction can be expected.

### PRIOR ART DOCUMENT

### Patent Document

Patent Document 1: JP-A-7-281021

### DISCLOSURE OF INVENTION

### Technical Problem

However, highly purified glass raw materials wherein the contents of U and Th are little, require high raw material costs, since their purification step requires time and effort, or a dedicated purification equipment, and further, it is necessary to use a crucible or a melting furnace made of a platinum-type material in order to avoid inclusion of impurities containing radioisotopes from the glass production step, which becomes a factor to increase the production cost. Further, with respect to glass raw materials such as TiO₂, ZrO₂, etc. from which separation of α ray emission elements by purification is difficult, there will be such a restriction that their use should be avoided at a portion where the glass raw materials are in contact with the production equipment, or their use should be avoided as glass raw materials themselves.

The present invention has been made under the above circumstances, and it is an object of the present invention to provide a near infrared cutoff filter which is useful as cover glass for a solid state imaging sensor package, at low costs, by forming a thin film attenuation layer to effectively shield α rays emitted from a substrate glass in a form not to influence the optical characteristics, even in a case where substrate glass emitting a certain amount of α rays is used as a constituting member of the near infrared cutoff filter.

### Solution to Problem

Heretofore, in order to use a near infrared cutoff filter made of fluorophosphate glass or phosphate glass, as a cover glass for a solid state imaging sensor package, no other method has been studied other than the above-described method of strictly controlling the amount of α rays emitted from glass by using high purity glass raw materials.

Whereas, the present inventors have found that while allowing a certain amount of α rays emitted from substrate glass as a constituting member of a near infrared cutoff filter, a thin film attenuation layer not to influence the optical characteristics is formed on the substrate glass surface, whereby it is possible to attenuate α rays emitted from the substrate glass thereby to certainly prevent malfunction of a solid state imaging sensor even when such a near infrared cutoff filter is used as cover glass for a solid state imaging sensor package.

That is, the near infrared cutoff filter of the present invention comprises substrate glass made of fluorophosphate glass containing CuO or phosphate glass containing CuO, and a thin film attenuation layer formed on at least one light-permeable surface of the substrate glass to attenuate α rays emitted from the substrate glass.

Further, such a thin film attenuation layer is preferably formed by a method selected from a CVD method, a sputtering method, an ion assisted vapor deposition method and a coating method.

Further, the thin film attenuation layer preferably has at least one function selected from antireflection, infrared cutoff, and ultraviolet and infrared cutoff.

Further, the thin film attenuation layer preferably has a density (g/cm³)×thickness (μm) of from 2 to 50.

Further, it is preferred that the substrate glass has its edge face chamfered, the chamfered portion is subjected to etching treatment so that the maximum value of the crack length at a ridge line of the chamfered portion is at most 0.02 mm, and the bending strength of the near infrared cutoff filter is at least 65 N/mm².

Further, it is preferred that a thin film attenuation layer is formed on one light-permeable surface of the substrate glass, and a stress relaxation layer is formed on the other light-permeable surface, so that when an internal stress formed in the thin film attenuation layer is a compression stress, the internal stress in the stress relaxation layer becomes a compression stress of an equal degree, and when an internal stress formed in the thin film attenuation layer is a tensile stress, the internal stress in the stress relaxation layer becomes a tensile stress of an equal degree.

Further, the α ray emission from the substrate glass is preferably from 0.05 to 1.0 c/cm²·h.

Further, the near infrared cutoff filter preferably has an α ray attenuation rate of at least 20% as obtained by the following formula: α ray attenuation rate=([A]-[B])/[A], where [A] is the α ray emission from the substrate glass when no thin film attenuation layer is formed, and [B] is the α ray emission from the substrate glass when the thin film attenuation layer is formed.

Further, the cover glass for a solid state imaging sensor package of the present invention is cover glass for a solid state imaging sensor package to be attached to an opening of a solid state imaging sensor package, which cover glass is made of the above near infrared cutoff filter having the thin film attenuation layer formed on a light-permeable surface facing the solid state imaging sensor, of the cover glass for a solid state imaging sensor package.

Further, the solid state imaging sensor package of the present invention is a solid state imaging sensor package having a solid state imaging sensor accommodated therein and having the above near infrared cutoff filter attached, as cover glass, to an opening of the solid state imaging sensor package. In this solid state imaging sensor package, the near infrared cutoff filter is preferably attached so that the thin film attenuation layer of the filter faces the solid stage imaging sensor.

### Advantageous Effects of Invention

According to the present invention, even in a case where substrate glass emitting a certain amount of α rays is used as a constituting member of a near infrared cutoff filter, it is possible to provide a near infrared cutoff filter which is useful as cover glass for a solid state imaging sensor package, at low costs, by forming a thin film attenuation layer to effectively attenuate α rays emitted from the substrate glass in a form not to influence the optical characteristics.

### BRIEF DESCRIPTION OF DRAWINGS

FIG. 1 is a cross-sectional view of one embodiment wherein the near infrared cutoff filter according to the present invention is attached to a solid state imaging sensor package.

FIG. 2 is a cross-sectional view of another embodiment wherein the near infrared cutoff filter according to the present invention is attached to a solid state imaging sensor package.

FIG. 3 is a flowchart showing an embodiment of the process for producing a near infrared cutoff filter according to the present invention.

### DESCRIPTION OF EMBODIMENTS

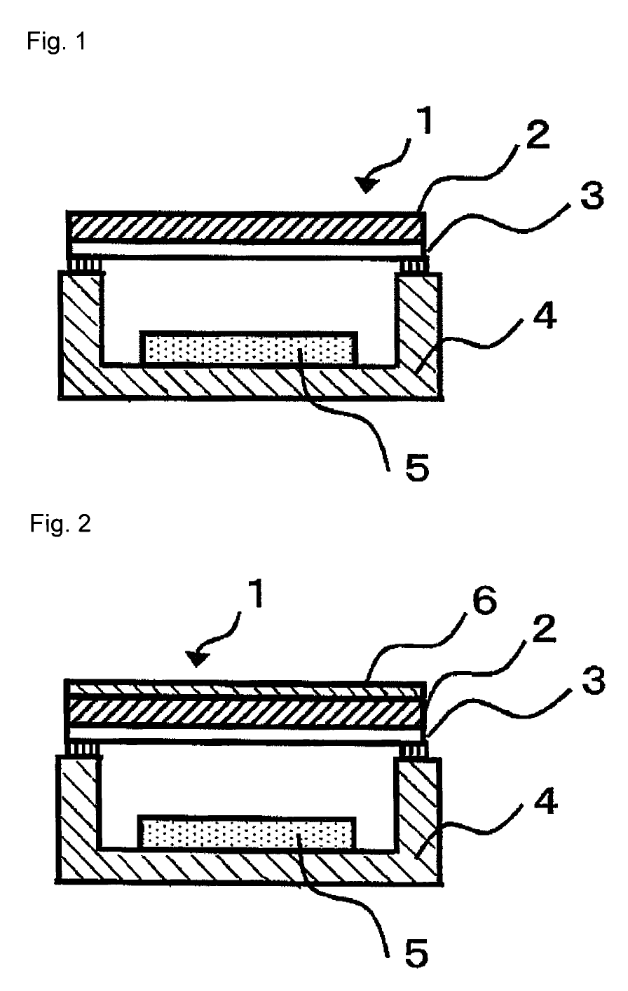

Now, embodiments of the near infrared cutoff filter according to the present invention will be described. FIGS. 1 and 2 are cross-sectional views of the respective embodiments wherein the near infrared cutoff filter 1 of the present invention is attached to a solid state imaging sensor package 4.

The near infrared cutoff filter 1 has a rectangular plate-form outer shape and comprises substrate glass 2 to shield near infrared rays while permeating visible light, and a thin film attenuation layer 3 formed on a light-permeable surface facing the solid state imaging sensor 5, of the substrate glass 2. The substrate glass 2 emits α rays derived from radioisotopes contained as impurities in the glass composition, but such α rays are attenuated by the thin film attenuation layer 3 formed on the substrate glass 2. It is thereby possible to prevent α rays from reaching the solid state imaging sensor 5, even if a near infrared cutoff filter 1 employing substrate glass 2 which emits αrays, is attached to a solid state imaging sensor package 4, and accordingly, the possibility of malfunction of the solid state imaging sensor 5 due to α rays will be low.

The substrate glass 2 is made of fluorophosphate glass containing CuO or phosphate glass containing CuO.

A solid state imaging sensor 5 such as CCD or CMOS which is used in a digital still camera or a video camera has a spectral sensitivity covering from the visible region to a near infrared region in the vicinity of 1,100 nm. Accordingly, as it is, it is not possible to obtain good color reproducibility, and it is necessary to correct the sensitivity to a usual sensitivity by means of a filter to absorb the infrared region. For this purpose, by using the substrate glass 2 having the above-mentioned glass composition, it is possible to property cutoff the near infrared rays.

The fluorophosphate glass has excellent weather resistance, and by incorporating CuO in glass, the near infrared rays can be absorbed, while maintaining a high transmittance of the visible light region, whereby it can be suitably used as the substrate glass 2 for the near infrared cutoff filter 1. Further, the thermal expansion coefficient of the fluorophosphate glass is about 130×10⁻⁷/° C., which is close to the thermal expansion coefficient of a resin package 4 to accommodate the solid state imaging sensor 5, and accordingly, it can also suitably be used as cover glass for the solid state imaging sensor package.

The fluorophosphate glass to be used in the present invention may be a known glass composition for a near infrared cutoff filter, but particularly from the viewpoint of excellent processing strength, it is preferred to use fluorophosphate glass having the following composition, wherein the content ratio of components for forming the network structure of glass is high. That is, it is preferably a fluorophosphate glass comprising, as represented by mass % calculated as the following oxides and fluorides, from 46 to 70% of P₂O₅, from 0 to 25% of MgF₂, from 0 to 25% of CaF₂, from 0 to 25% of SrF₂, from 0 to 20% of LiF, from 0 to 10% of NaF, from 0 to 10% of KF, from 1 to 30% of LiF+NaF+KF, from 0.2 to 20% of AlF₃, from 2 to 15% of ZnF₂ (provided that with respect to fluorides of MgF₂, CaF₂, SrF₂, LiF, NaF, KF, AlF₃ and ZnF₂, up to 50% of the total amount of these fluorides may be substituted by oxides), and from 1 to 15% of CuO. Further, from the viewpoint of containing radioisotopes, the above fluorophosphate glass is preferably permitted to contain Ba and Pb only as impurities.

In this specification, “ to ” is used to include the numerical values before and after “to” as the lower limit and upper limit values, unless otherwise specified.

The reasons for defining the contents of the respective components in the fluorophosphate glass within the above ranges, are as follows.

P₂O₅ is the main component to form the network structure of glass, and if it is less than 46%, the stability of glass tends to deteriorate, or the thermal expansion coefficient tends to increase, whereby the thermal shock resistance tends to deteriorate. If it exceeds 70%, the chemical durability tends to deteriorate. It is preferably from 48 to 65%.

AlF₃ is a component to improve the chemical durability and to increase the viscosity of glass, but if it is less than 0.2%, such an effect cannot be obtained, and if it exceeds 20%, vitrification tends to be difficult. It is preferably from 2 to 15%.

MgF₂, CaF₂ or SrF₂ is effective to stabilize glass without lowering the chemical durability, but if each exceeds 25%, the melting temperature tends to be high, or devitrification is likely to take place. Preferably, MgF₂ is at most 15%, and CaF₂ is within a range of from 5 to 15%. SrF₂ is also effective to improve the chemical durability of glass, but if it exceeds 25%, devitrification tendency tends to increase, and preferably, it is at most 10%.

LiF, NaF or KF is a component effective to lower the melting temperature. However, if LiF exceeds 20%, or if NaF or KF exceeds 10%, the chemical durability tends to deteriorate, and the thermal shock resistance tends to deteriorate. Further, if the total amount of LiF, NaF and KF (i.e. LiF+NaF+KF) is less than 1%, the effect to lower the melting temperature cannot be obtained, and if it exceeds 30%, the chemical durability is remarkably deteriorated, and LiF+NaF+KF is preferably within a range of from 1 to 30%. Preferably, LiF is from 4 to 15%, NaF is at most 5%, and KF is at most 5%, and their total amount (LiF+NaF+KF) is more preferably from 5 to 20%.

ZnF₂ is effective to improve the chemical durability and to lower the thermal expansion coefficient, but if it is less than 2%, such effects cannot be obtained, and if it exceeds 15%, the glass tends to be unstable, such being undesirable. Preferably, it is within a range of from 2 to 10%.

Further, the above-mentioned fluorides of MgF₂, CaF₂, SrF₂, LiF, NaF, KF, Alf₃ and ZnF₂ may be substituted by oxides up to 50% of the total amount of such fluorides. In such a case, O (oxygen) increases the thermal shock resistance and contributes to coloration of glass by Cu²⁺ ions, but if it exceeds 50%, the melting temperature tends to be high, and Cu²⁺ is likely to be reduced, whereby the desired spectral transmittance may not be obtainable.

In the above fluorophosphate glass, inclusion of Ba and Pb is allowed only as impurities, and they are preferably not substantially contained. In a conventional near infrared cutoff filter using a fluorophosphate glass as the basic glass, Ba and Pb are contained as BaF₂ and PbF₂ for the purpose of stabilizing the glass and improving the weather resistance. However, in a case where a near infrared cutoff filter is used as a window glass for a solid state imaging sensor package, the amount of α rays emitted from the glass is required to be low, and accordingly, BaF₂ or PbF₂ having a large content of radioisotopes in the raw material is preferably not substantially contained. Further, Pb is preferably not contained also from the viewpoint of an environment polluting substance.

Phosphate glass has a high hardness as compared with fluorophosphate glass and is hardly breakable when an external force such as bending force is exerted. Further, by incorporating CuO in glass, it is possible to absorb near infrared rays while maintaining a high transmittance of the visible light region, and accordingly, it can be suitably used as the substrate glass 2 for the near infrared cutoff filter 1. Further, the thermal expansion coefficient of phosphate glass is about 80×10⁻⁷/° C., which is close to the thermal expansion coefficient of an alumina ceramic package 4 accommodating a solid state imaging sensor 5, and thus it can be suitably used as cover glass for a solid state imaging sensor package.

The phosphate glass to be used in the present invention may have a known glass composition for a near infrared cutoff filter, but it is, for example, preferably a composition comprising, as represented by mass % calculated as the following oxides, from 70 to 85% of P₂O₅, from 8 to 17% of Al₂O₃, from 1 to 10% of B₂O₃, from 0 to 3% of Li₂O, from 0 to 5% of Na₂O, from 0 to 5% of K₂O, from 0.1 to 5% of Li₂O+Na₂O+K₂O, and from 0 to 3% of SiO₂ and from 1 to 15% of CuO.

The reasons for defining the contents of the respective components in the phosphate glass to be within the above ranges, are as follows.

P₂O₅ is the main component to constitute the glass network, but if it is less than 70%, the melting property tends to deteriorate, and if it exceeds 85%, devitrification is likely to take place.

Al₂O₃ is a component essential to improve the chemical durability of glass, but if it is less than 8%, such an effect is not obtainable, and if it exceeds 17%, the melting property tends to deteriorate.

B₂O₃ is a component effective to improve the chemical durability and effective for the stability of glass, but if it is less than 1%, such effects will not be obtainable, and if it exceeds 10%, devitrification tendency tends to increase.

Li₂O, Na₂O or K₂O is added to improve the melting property of glass thereby to prevent devitrification. However, if their total content (Li₂O+Na₂O+K₂O) is less than 0.1%, such effects are not obtainable, and if it exceeds 5%, the chemical durability tends to deteriorate.

SiO₂ is effective to improve the chemical durability, but if it exceeds 3%, the chemical durability extremely deteriorates.

CuO contained in the above-described fluorophosphate glass or phosphate glass is an essential component to cutoff near infrared rays. If CuO is not contained, near infrared rays cannot be substantially cutoff, and it becomes impossible to let the filter have a near infrared cutoff function. CuO is an essential component to impart an infrared-absorbing ability to glass when incorporated in the glass. However, if it is less than 1%, such an effect is not sufficient, and if it exceeds 15%, the stability of the glass tends to be low, such being undesirable.

A solid state imaging sensor 5 is susceptible to a soft error due to α rays emitted from cover glass for the solid state imaging sensor package, and therefore, heretofore, it has been attempted to reduce the amount of radioisotopes contained in the cover glass as far as possible. Radioisotopes emitting α rays may, for example, be typically U (uranium), Th (thorium) and Ra (radium). These elements are contained in very small amounts as impurities in glass raw materials. It may not be impossible to separate such radioisotopes from the glass raw materials, but costs for purification of raw materials for such separation are very high, and there is a problem that by carrying out such separation, the costs for a near infrared cutoff filter 1 become high.

Under these circumstances, with the near infrared cutoff filter 1 of the present invention, it has been made to suppress costs for a near infrared cutoff filter 1 to be low by using inexpensive glass raw materials which are not subjected to an operation to separate radioisotopes which causes an increase of costs of the glass raw materials. That is, it has been made possible to positively use substrate glass 2 which emits a certain amount of α rays. In order to use the substrate glass 2 which emits a certain amount of αrays, the thin film attenuation layer 3 is provided on the substrate glass 2 to attenuate α rays emitted from the substrate glass 2, whereby it becomes possible to bring the α ray emission to the same level as the near infrared cutoff filter made of expensive glass raw materials subjected to an operation to separate radioisotopes.

In the near infrared cutoff filter 1 of the present invention, the contents of radioisotopes in the substrate glass 2 are preferably from 10 ppb to 50 ppb of U and from 30 ppb to 70 ppb of Th. By using such substrate glass 2, the α ray emission of the substrate glass itself will be from 0.05 to 1.0 c/cm²·h, but α rays are attenuated by the thin film attenuation layer 3 provided on the substrate glass 2, whereby the amount of α rays reaching the solid state imaging sensor 5 will be substantially reduced. As the near infrared cutoff filter 1 of the present invention is provided with such a structure, it becomes possible to allow a certain amount of α rays emitted from the substrate glass 2, and it becomes possible to produce the substrate glass 2 at low costs.

The near infrared cutoff filter 1 of the present invention is preferably such that the substrate glass has its edge face chamfered, the chamfered portion is subjected to etching treatment so that the maximum value of the crack length at a ridge line of the chamfered portion is at most 0.02 mm, and the bending strength of the near infrared cutoff filter is at least 65 N/mm².

In a case where the near infrared cutoff filter 1 is used as cover glass for a solid state imaging sensor package, the substrate glass 2 is required to have a high strength equal to borosilicate glass used as a conventional cover glass. With the fluorophosphate glass or phosphate glass to be used for the substrate glass 2, the hardness of glass is low as compared with borosilicate glass, and there is a problem that when the optically functional surface is subjected to optical polishing, a fine chip is likely to be formed at the edge. Therefore, there is a question in reliability such that in a step for producing a solid state imaging sensor, for example, in a state where the temperature change is large as in a solder reflow step, a fine chip at the edge is likely to become a starting point for cracking.

Whereas, by subjecting a ridge line of the chamfered portion of the substrate glass 2 to etching treatment after the chamfering, it is possible to remove fine cracks formed in the chamfering step or cracks formed in a step prior to the chamfering step. It is thereby possible to bring the maximum value of the crack length at the ridge line to be at most 0.02 mm. Here, the maximum value of the crack length at the ridge line is at most 0.02 mm and preferably close to zero as far as possible. In the present invention, the crack at the ridge line is meant for a crack which intersects with the ridge line. Further, in the present invention, the crack length at the ridge line is meant for the length of a crack in a case where with respect to a crack which extends on the surface or interior of the near infrared cutoff filter 1 from the ridge line as the starting point, the crack is projected on the surface (the side surface or light-permeable surface) of the near infrared cutoff filter 1.

Further, the bending strength of the near infrared cutoff filter 1 is at least 65 N/mm² and preferably close to the strength of the material as far as possible.

The type of external force exerted to glass may be different depending upon the type wherein the near infrared cutoff filter 1 is used, but it is considered that the bending strength of glass can be an index for the strength of the glass in various applications. And as a result of an investigation on the relation between the strength required for an application to cover glass for a solid state imaging sensor package and the strength of the glass itself, it has been found that a certain reliability can be secured when the bending strength is at least 65 N/mm². Further, an investigation has been made on a crack at the ridge line which causes breakage when a bending stress is exerted to glass, and it has been found that there is an interrelation between the crack length and the bending strength, and in a fluorophosphate glass having a lower glass hardness than a phosphate glass, the bending strength can be made to be at least 65 N/mm² in a case where the maximum value of the crack length is at most 0.02 mm. On the basis of such a finding, the present inventors found it possible to obtain a suitable strength as a near infrared cutoff filter 1 which can be used as cover glass for a solid state imaging sensor package, by adjusting the maximum value of the crack length at the ridge line of the substrate glass to be at most 0.02 mm and the bending strength to be at least 65 N/mm².

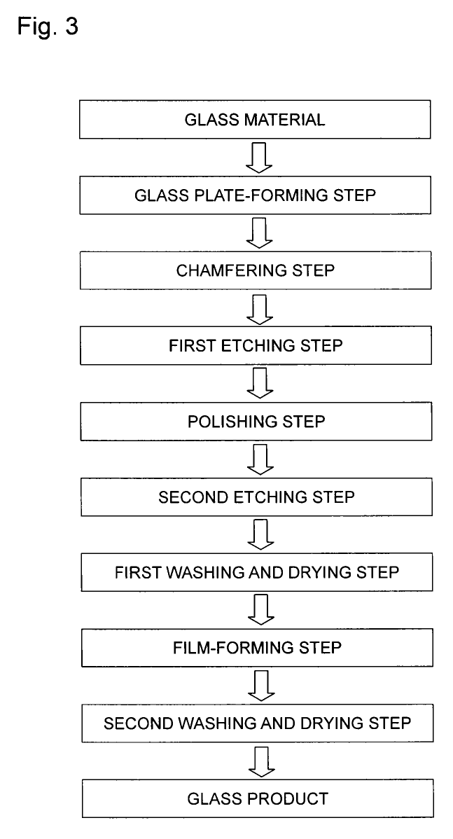

A process including etching treatment for obtaining a substrate glass 2 for the maximum value of the crack length at the ridge line being at most 0.02 mm and the bending strength of the near infrared cutoff filter being at least 65 N/mm², will be described. FIG. 3 is a flowchart showing an embodiment of the process for producing the substrate glass 2.

Now, the flow of the process from a glass material to a glass product will be briefly described in accordance with FIG. 3. Firstly, a glass material is melted and formed to obtain a flat glass plate (glass plate-forming step). This glass plate is cut into a prescribe size, and the ridge line is chamfered by means of e.g. a diamond wheel (chamfering step). The glass plate is immersed in an etching solution made of an acidic aqueous solution wherein the acidic component is hydrochloric acid to carry out etching treatment to remove cracks formed at the ridge line in the chamfering step (first etching step). The optically functional surface of this glass plate is polished to obtain a mirror surface (polishing step). Then, in order to remove or minimize fine cracks formed at the ridge line of the glass plate in the polishing step, the glass plate is immersed in an etching solution made of an alkaline aqueous solution to carry out etching treatment (second etching step). The glass plate is washed to sufficiently remove the abrasive or polishing debris, followed by drying (first washing and drying step). On the polished surface of the glass plate thus obtained, film forming is carried out, as the case requires, to form e.g. an antireflection film or a near infrared cutoff film (film forming step). And, the glass substrate is washed and dried (second washing and drying step), thereby to obtain a glass product.

The thin film attenuation layer 3 is one to be formed on at least one light permeable surface of the above substrate glass 2 to attenuate α rays emitted from the substrate glass 2.

The thin film attenuation layer 3 is required to be one not to adversely influence the optical characteristics of the near infrared cutoff filter 1. The near infrared cutoff filter 1 is disposed on an optical path of light entering the solid state imaging sensor 5, and it is not desirable that the amount of light is substantially decreased by passing through the thin film attenuation layer 3 or unintended color compensation is done. Further, the near infrared cutoff filter 1 is disposed at a position close to a solid state imaging sensor 5, and accordingly, if the thin film attenuation layer 3 formed on the substrate glass 2 has a defect (foreign matter), such a defect will be included in the image. Therefore, the thin film attenuation layer 3 is also required to be free from such a defect. The thin film attenuation layer 3 preferably presents substantial permeability to light in the visible region and further preferably has a transmittance of at least 90% to light in the visible region.

Further, the thin film attenuation layer 3 preferably has a density (g/cm³)×thickness (μm) of from 2 to 50. As mentioned above, it is essential that the thin film attenuation layer 3 does not adversely influence the optical characteristics of the near infrared cutoff filter 1, and the thickness of the thin film attenuation layer 3 is preferably as thin as possible. On the other hand, the ability to attenuate α rays of the thin film attenuation layer 3 is higher as the thickness of the layer becomes thick. The present inventors have paid attention to the density of the layer in order to reduce the thickness of the thin film attenuation layer 3 as far as possible, and have found that by adjusting the relation of the density×thickness to be at least a certain level, α rays can certainly be attenuated by the thin film attenuation layer 3. It is thereby possible to avoid making the thickness of the thin film attenuation layer 3 to be thicker than necessary thereby to minimize the influence over the optical characteristics of the near frared cutoff filter 1. If the density (g/cm³)×thickness (μm) of the thin film attenuation layer 3 is less than 2, the ability to attenuate α rays tends to be inadequate, and if it exceeds 50, the optical characteristics are likely to be influenced, such being undesirable. More preferably, it is within a range of from 10 to 46. Further, the film thickness not to influence the optical characteristics of the near infrared cutoff filter 1 is preferably less than 40 μm. On the other hand, the same film thickness is preferably at least 0.2 μm to obtain the effect to attenuate α rays.

Here, the ability of the thin film attenuation layer 3 to attenuate α rays from the substrate glass 2 is preferably as high as possible, and it is preferably at least 1%, more preferably at least 4%, further preferably at least 20%, still further preferably at least 40%, as the α ray attenuation rate. The α ray attenuation rate is one calculated by ([A]-[B])/[A], where [A] is the α ray emission from the substrate glass 2 when no thin film attenuation layer 3 is formed, and [B] is the α ray emission from the substrate glass 2 when the thin film attenuation layer 3 is formed.

The thin film attenuation layer 3 may, for example, be preferably a dielectric multilayer film, silicon oxide, silicon oxynitride or various resin coatings.

As a resin to be used for the thin film attenuation layer 3 in the present invention, a commonly commercially available polyacrylate, polymethacrylate, polyester, polyvinyl ether, polyethylene terephthalate, polycarbonate, polystyrene, polyvinylchloride, polysulfone, cellulose, polyimide, polyamide, polyurethane, an epoxy resin, a fluoro resin or a copolymer of such a resin may suitably be used. Further, to such a resin, crosslinking sites may be introduced as the case requires. The chemical structure of such crosslinking sites is not particularly limited so long as it is reactive with a monomer constituting the above resin. A crosslinking site may be introduced to some of monomer units of the above resin, but all monomer units may be made of crosslinking sites.

The above resin may be dissolved in an organic solvent to form a solution and then formed into a film by applying the solution on a substrate glass 2 of the near infrared cutoff filter 1 by a coating method such as a spin coating method or a bar coating method, or a polymerizable monomer is applied on the substrate glass 2 and then subjected to polymerization reaction by light, heat or radiation to cure and form a film.

In the case of employing the latter method, a photopolymerization initiator or a thermal polymerization initiator may preliminarily be added to the polymerizable monomer. As the photopolymerization initiator, acetophenones, benzophenones, benzoins, benzyls, Michler ketones, benzoin alkyl ethers, benzyl methyl ketals and thioxanthones may, for example, be mentioned. As the thermal polymerization initiator, benzoyl peroxides, bisazobutyronitriles, etc. may be mentioned. As the polymerization initiator, one type or two or more types may be used in each category of the photopolymerization initiator and the thermal polymerization initiator. The amount of the polymerization initiator is preferably from 0.005 to 5 mass %, based on the total amount of polymerizable monomers.

Further, the thin film attenuation layer 3 preferably has at least one function selected from antireflection, infrared cutoff, and ultraviolet and infrared cutoff. In a case where the thin film attenuation layer 3 has an antireflection function, the amount of reduction as reflected by the thin film attenuation layer 3, of visible light passing through the near infrared cutoff filter 1 becomes small, and it becomes possible to have good optical characteristics.

In a case where the thin film attenuation layer 3 has an infrared cutoff or ultraviolet and infrared cutoff function, in addition to the optical characteristics of the substrate glass 2 itself, the above optical characteristics can be imparted to the near infrared cutoff filter 1.

With respect to a method for forming the thin film attenuation layer 3, it is preferred that the attenuation layer is formed by a method selected from a CVD method, a sputtering method, an ion assisted vapor deposition method and a coating method.

By the CVD method, it becomes possible to form a thin film to cover and shield a foreign substance present on the substrate glass 2 and it becomes possible to substantially reduce the number of defects, whereby a possible problem at the time of detecting an image by the solid state imaging sensor 5 can be reduced. The CVD method may be either one of so-called reduced pressure CVD method and normal pressure CVD method, or any type of CVD method such as a photo CVD method, a plasma CVD method or a thermal CVD method.

By the sputtering method or the ion assisted vapor deposition method, the thin film attenuation layer 3 may be formed at a high density on the substrate glass 2. It is thereby possible to minimize an influence to the optical characteristics of the near infrared cutoff filter 1, since the thin film attenuation layer 3 is capable of attenuating α rays with a thin layer thickness.

As the coating material, a commercial material is available wherein the content of U, Th and Ra as impurities in the material to be used is at most 50 ppb in the total of the three types, and therefore, the production becomes possible without requiring any substantial change in production, such being advantageous from the viewpoint of costs.

The thin film attenuation layer 3 has a problem such that if it is formed on a substrate glass 2 in a high density state by means of the above-mentioned sputtering method or ion assisted vapor deposition method, the internal stress of the layer becomes large, and the near infrared cutoff filter 1 is likely to be thereby warped. Therefore, as in the embodiment shown in FIG. 2, it is preferred that a stress relaxation layer 6 having a stress of the same degree and in the same direction as the above thin film attenuation layer 3, is formed on the other light-permeable surface having no thin film attenuation layer 3 formed, of the substrate glass 2. The internal stress of the thin film attenuation layer 3 is thereby cancelled by the stress relaxation layer 6, whereby warpage of the near infrared cutoff filter 1 is suppressed. Further, the stress relaxation layer 6 is required to present no adverse effect to optical characteristics of the near infrared cutoff filter 1 like the thin film attenuation layer 3. Here, the stress relaxation layer 6 having a stress having the same degree and in the same direction as the thin film attenuation layer 3 is one adjusted so that when an internal stress formed in the thin film attenuation layer 3 is a compression stress, the internal stress in the stress relaxation layer 6 becomes a compression stress of an equal degree, and when an internal stress formed in the thin film attenuation layer 3 is a tensile stress, the internal stress in the stress relaxation layer 6 becomes a tensile stress of an equal degree.

The near infrared cutoff filter 1 of the present invention can be used as cover glass for a solid state imaging sensor package to be attached to an opening of a solid state imaging sensor package 4. In a case where the near infrared cutoff filter 1 is used as cover glass for a solid state imaging sensor package, it is disposed so that at least the thin film attenuation layer 3 is formed on the surface facing the solid state imaging sensor 5. Thus, α rays emitted from the substrate glass 2 are attenuated by the thin film attenuation layer 3, whereby the solid state imaging sensor 5 disposed in the solid state imaging sensor package 4 becomes scarcely susceptible to a soft error caused by α rays.

Now, the near infrared cutoff filter 1 of the present invention will be described with reference to Examples and Comparative Examples. In the following Examples and Comparative Examples, as the substrate glass 2 for the near infrared cutoff filter 1, a plate-form fluorophosphates glass having a size of 33.7 mm×50.8 mm and a thickness of 0.3 mm was used. The composition of the fluorophosphate glass comprises, as represented by mass % calculated as the following oxides and fluorides, 46.2% of P₂O₅, 1.9% of MgF₂, 8.4% of CaF₂, 18.3% of SrF₂, 9.0% of NaF, 9.9% of Alf₃, 2.2% of MgO, 9.0% of LiF+NaF+KF and 6.2% of CuO. Further, the substrate glass 2 contains substantially no Ba or Pb.

This glass was prepared as follows. Firstly, raw materials were weighed and mixed so that the obtainable glass would be within the above-mentioned composition range, and this raw material mixture was put in a platinum crucible and, after putting a cover, heated and melted at a temperature of from 780 to 1,100° C. in an electric furnace. After sufficiently stirring and clarifying, the melt was cast in a mold, annealed and then cut to obtain a flat plate of 125 mm square. This plate was roughly polished to a thickness of 1 mm by a both side polishing machine using #600 carbon type abrasive grains and cut into a prescribed size by a scribe machine using a diamond superhard blade, to obtain a plate glass.

In the chamfering step, the cut rectangular plate glass was chamfered by chamfering eight ridge lines of the four edge faces of the rectangular plate glass by means of a multi-grooved wheel for cam-type profile grinding along a standard shape by means of an abrasive wheel having a plurality of V-grooves. The abrasive wheel used in the chamfering step is a diamond electrodeposited grinding wheel (#400).

In the first etching step, as the etching solution, one having 1 mass % of a surfactant (polyoxyethylene alkyl ether) added to an etching solution (aqueous solution) containing 20 mass % of HCI, was used, and the plate glass after the above chamfering step was immersed for 10 minutes in an etching apparatus. With the etching solution and equipped with an ultrasonic wave-generating mechanism and an up and down swinging mechanism.

In the polishing step, the front and rear surfaces (optically functional surfaces) of the plate glass were lapped with #1200 alumina-type abrasive grains by a both side polishing machine to carry out rough finish of the surface and grinding of the plate to a thickness of about 0.3 mm. Then, this glass product was subjected to polishing treatment with a ceria-type abrasive material by a both side polishing machine to carry out mirror finish of the glass surfaces.

In the second etching step, as the etching solution, an etching solution (aqueous solution) containing 50 mass % of KOH as an alkali component was used, and the plate glass after the above polishing step was immersed for 10 minutes in the above etching solution heated to about 40° C.

Other production steps were carried out in accordance with the flowchart shown in FIG. 3 (provided that there was no film-forming step).

With respect to the prepared substrate glass 2, the bending strength (maximum value) was measured by a three point bending strength test disclosed in JIS R1601 “Method for testing bending strength of fine ceramics”, and it was 198.1 N/mm². Further, the ridge lines were confirmed by an optical microscope, to confirm the maximum value of the crack length, but no crack was confirmed. Here, the bending strength and the maximum value of the crack length were measured with respect to 30 sheets of each glass.

In an Example, each type of the thin film attenuation layer 3 was formed on a substrate glass 2 made of the above fluorophosphate glass, and the α ray emission from the surface having the thin film attenuation layer 3 was measured. The α ray emission was measured by using a low level α ray measuring apparatus (LACS-4000M manufactured by Sumitomo Chemical Co., Ltd.). Further, in Comparative Example 1, the α ray emission was measured in a state where only the substrate glass 2 was present without using the thin film attenuation layer 3.

The details of the thin film attenuation layer 3 and the α ray emission in each of Examples and Comparative Examples are shown in Table 1.

TABLE 1

| | Thin film attenuation layer | | | α ray | α ray | | |
|---|---|---|---|---|---|---|---|
| | | Layer | | emission | attenuation | | Thickness × |
| | Material | thickness | Forming method | (c/cm²h)(\textcircled{2}) | rate | Function | density |
| Ex. 1 | Single layer of SiO₂ | 90 nm | Ion assisted vapor | 0.4654 | 4.69% | Antireflection | — |
| | | | deposition method | | | | |
| Ex. 2 | Single layer of SiO₂ | 450 nm | Ion assisted vapor | 0.4468 | 8.50% | | — |
| | | | deposition method | | | | |
| Ex. 3 | Single layer of SiO₂ | 10 μm | CVD method | 0.1231 | 74.79% | | 10 |
| Ex. 4 | Single layer of SiON | 10 μm | CVD method | 0.0934 | 80.87% | | 23 |
| Ex. 5 | Single layer of SiON | 20 μm | CVD method | 0.0211 | 95.68% | | 46 |
| Ex. 6 | Ta₂O₅/SiO₂ (7 layers) | 250 nm | Ion assisted vapor | 0.3893 | 20.27% | | — |
| | | | deposition method | | | | |
| Ex. 7 | Ta₂O₅/SiO₂ (40 layers) | 5 μm | Ion assisted vapor | 0.2827 | 42.11% | UV-IR cutoff | — |
| | | | deposition method | | | | |
| Ex. 8 | Ta₂O₅/SiO₂ (7 layers) | 250 nm | Vacuum vapor | 0.4791 | 1.88% | Antireflection | — |
| | | | deposition method | | | | |
| Ex. 9 | Silicone-type rubber | 13 μm | Die coat | 0.1919 | 60.70% | Antireflection | 13 |
| Ex. 10 | Silicone-type rubber | 32 μm | Die coat | 0.0615 | 87.40% | Antireflection | 32 |
| Comp. Ex. | — | | — | 0.4883(\textcircled{1}) | — | — | — |

* α ray attenuation rate = (\textcircled{1} − \textcircled{2})/\textcircled{1}

From Table 1, it is evident that it is possible to attenuate α rays emitted from a substrate glass 2 by forming a thin film attenuation layer 3 on the substrate glass 2. Examples 6 and 8 represent cases where similar dielectric multilayer films were formed by different film-forming methods, i.e. Example 6 is one formed by an ion assisted vapor deposition method, and Example 8 is one formed by a vapor deposition method without ion assist. That is, they are different only in the condition of the presence or absence of ion assist. From the comparison, it is evident that by forming the thin film attenuation layer 3 at a high density by means of ion assist, a substantial difference is made in the ability to attenuate α rays even in the same film thickness. Example 5 is one having the thickness of the thin film attenuation layer 3 made thick by using the same material as in Example 4, whereby it was confirmed that the α ray emission decreased. That is, it has been evidenced that also the thickness of the film is influential over the shielding effect. Examples 9 and 10 are ones having an organic film used as the thin film attenuation layer 3. It is evident that α rays can be shielded by forming an organic film on the substrate glass 2. Further, the thin film attenuation layers in Examples 1 to 6 and 8 have antireflection properties, and the thin film attenuation layer in Example 7 has an ultraviolet and infrared cutoff properties. By forming such thin film attenuation layers on substrate glass, it is possible to impart functions of such optical properties.

### INDUSTRIAL APPLICABILITY

According to the present invention, it is possible to provide at low costs a near infrared cutoff filter which can be used as cover glass for a solid state imaging sensor package, by providing a thin film attenuation layer to effectively attenuate α rays emitted from a substrate glass 2 in a form not to influence the optical characteristics, even when substrate glass emitting a certain amount of α rays is used as a constituting member of the near infrared cutoff filter.

This application is a continuation of PCT Application No. PCT/JP2010/069523 filed on Nov. 2, 2010, which is based upon and claims the benefit of priority from Japanese Patent Application No. 2009-253255 filed on Nov. 4, 2009. The contents of those applications are incorporated herein by reference in its entirety.

### REFERENCE SYMBOLS

1: Near infrared cutoff filter, 2: substrate glass, 3: thin film attenuation layer, 4: solid state imaging sensor package, 5: solid state imaging sensor, 6: stress relaxation layer.

What is claimed is:

1. A near infrared cutoff filter comprising substrate glass made of fluorophosphate glass containing CuO or phosphate glass containing CuO, and a thin film attenuation layer formed on at least one light-permeable surface of the substrate glass to attenuate α rays emitted from the substrate glass.

2. The near infrared cutoff filter according to claim 1, wherein the thin film attenuation layer is formed by a method selected from a CVD method, a sputtering method, an ion assisted vapor deposition method and a coating method.

3. The near infrared cutoff filter according to claim 1, wherein the thin film attenuation layer has at least one function selected from antireflection, infrared cutoff, and ultraviolet and infrared cutoff.

4. The near infrared cutoff filter according to claim 1, wherein the thin film attenuation layer has a density (g/cm³)×thickness (μm) of from 2 to 50.

5. The near infrared cutoff filter according to claim 1, wherein the substrate glass has its edge face chamfered, the chamfered portion is subjected to etching treatment so that the maximum value of the crack length at a ridge line of the chamfered portion is at most 0.02 mm, and the bending strength of the near infrared cutoff filter is at least 65 N/mm².

6. The near infrared cutoff filter according to claim 1, wherein a thin film attenuation layer is formed on one light-permeable surface of the substrate glass, and a stress relaxation layer is formed on the other light-permeable surface, so that when an internal stress formed in the thin film attenuation layer is a compression stress, the internal stress in the stress relaxation layer becomes a compression stress of an equal degree, and when an internal stress formed in the thin film attenuation layer is a tensile stress, the internal stress in the stress relaxation layer becomes a tensile stress of an equal degree.

7. The near infrared cutoff filter according to claim 1, wherein the α ray emission from the substrate glass is from 0.05 to 1.0 c/cm²·h.

8. The near infrared cutoff filter according to claim 1, which has an α ray attenuation rate of at least 20% as obtained by the following formula:
α ray attenuation rate =([A]-[B])/[A], where [A] is the α ray emission from the substrate glass when no thin film attenuation layer is formed, and [B] is the α ray emission from the substrate glass when the thin film attenuation layer is formed.

9. Cover glass for a solid state imaging sensor package to be attached to an opening of a solid state imaging sensor package, which cover glass is made of the near infrared cutoff filter as defined in claim 1 having the thin film attenuation layer formed on a light-permeable surface facing the solid state imaging sensor, of the cover glass for a solid state imaging sensor package.

10. A solid state imaging sensor package having a solid state imaging sensor accommodated therein and having the near infrared cutoff filter as defined in claim 1 attached, as cover glass, to an opening of the solid state imaging sensor package.

11. The solid state imaging sensor package according to claim 10, wherein the near infrared cutoff filter is attached so that the thin film attenuation layer of the filter faces the solid state imaging sensor.
